(19) United States
(12) Patent Application Publication
(10) Pub. No.: US 2017/0134057 A1
(43) Pub. Date: May 11, 2017

(54) METHOD FOR PROCESSING SIGNAL AND ELECTRONIC DEVICE SUPPORTING THE SAME

(71) Applicant: SAMSUNG ELECTRONICS CO., LTD., Suwon-si (KR)

(72) Inventor: Hyung Gon KIM, Suwon-si (KR)

(21) Appl. No.: 15/341,207

(22) Filed: Nov. 2, 2016

(30) Foreign Application Priority Data
Nov. 6, 2015 (KR) 10-2015-0156070

(51) Int. Cl. H04B 1/10; H04B 1/16; H03F 3/213; H04B 1/18; H03F 3/195; H04L 12/851; H04B 1/40

(52) U.S. Cl. CPC H04B 1/1018; H04L 47/2441; H04B 1/16; H04B 1/40; H04B 1/18; H03F 3/195; H03F 3/213; H03F 2200/294; H03F 2200/111

(57) ABSTRACT

An electronic device is provided which includes an antenna that receives signals of multiple frequency bands from an external device, a receiver module including circuitry that classifies and amplifies the signals received through the antenna, a conducting wire unit that transmits the amplified signals through conducting wires, and a circuit unit including circuitry that processes a signal received through the conducting wire unit, wherein the receiver module classifies the signals into a plurality of groups and selectively connects signals, which belong to at least one group of the plurality of groups, with an amplifier through a switch.

### CROSS-REFERENCE TO RELATED APPLICATION

This application is based on and claims priority under 35 U.S.C. §119 to a Korean patent application filed on Nov. 6, 2015 in the Korean Intellectual Property Office and assigned Serial number 10-2015-0156070, the disclosure of which is incorporated by reference herein in its entirety.

### TECHNICAL FIELD

The present disclosure relates generally to a technology that allows an electronic device to send and receive signals of multiple frequency bands to and from an external device.

### BACKGROUND

An electronic device such as a smartphone, a tablet, or the like may perform a communication function by using an antenna. The electronic device may perform a voice call, a video call, wireless data communication, and the like by sending and receiving signals to and from an external device. Nowadays, there is being developed an electronic device that includes an antenna and a communication module to send and receive signals of multiple frequency bands.

In the case where a conventional electronic device operates in response to signals of multiple frequency bands, all signal lines that correspond respectively to frequency bands have to be arranged on a printed circuit board. In an electronic device such as a smartphone with a limited mounting space, the arrangement of the signal lines may cause interference with peripheral components (e.g., audio and power lines) and may make a design of the printed circuit board complicated. Also, since it is difficult (or impossible) to connect an amplifier to each signal line due to the limited mounting space, the performance of processing signals may decrease.

### SUMMARY

Aspects of the present disclosure address at least the above-mentioned problems and/or disadvantages and provide various advantages described below. Accordingly, an aspect of the present disclosure is to provide a signal processing method that can reduce the number of signal lines by grouping signals included in multiple frequency bands and selectively amplifying signals included in at least one group and an electronic device supporting the same.

In accordance with an example aspect of the present disclosure, an electronic device is provided, the electronic device including: an antenna configured to receive signals of multiple frequency bands from an external device, a receiver module comprising receiver circuitry configured to classify and amplify the signals received through the antenna, a conducting wire unit comprising circuitry configured to transmit the amplified signals, and a circuit unit comprising circuitry configured to process a signal received through the circuitry of the conducting wire unit, wherein the receiver circuitry of the receiver module is configured to classify the signals into a plurality of groups and to selectively connect signals which belong to at least one group of the plurality of groups, with an amplifier through a switch.

Other aspects, advantages, and salient features of the disclosure will become apparent to those skilled in the art from the following detailed description, which, taken in conjunction with the annexed drawings, discloses various example embodiments of the present disclosure.

### BRIEF DESCRIPTION OF THE DRAWINGS

The above and other aspects, features, and advantages of the present disclosure will be more apparent from the following detailed description, taken in conjunction with the accompanying drawings, in which like reference numerals refer to like elements, and wherein:

FIG. 1 is a block diagram illustrating an example electronic device in a network environment, according to various example embodiments;

FIG. 2 is a block diagram illustrating an example communication interface, according to various example embodiments;

FIG. 3A is a block diagram illustrating an example configuration of a conversion unit, according to various example embodiments;

FIG. 3B is a block diagram illustrating an example configuration of an amplification unit, according to various example embodiments;

FIG. 4 is a flowchart illustrating an example signal processing method, according to various example embodiments;

FIG. 5 is a diagram illustrating example implementation of a communication interface, according to various example embodiments;

FIG. 6A is a flowchart illustrating an example method of receiving signals of a plurality of communication bands that are combined, according to various example embodiments;

FIG. 6B is a diagram illustrating an example communication interface that receives signals included in a plurality of communication bands, according to various example embodiments;

FIG. 7 is a diagram illustrating an example configuration of an electronic device, according to various example embodiments; and

FIG. 8 is a block diagram illustrating an example electronic device, according to various example embodiments.

Throughout the drawings, it should be noted that like reference numbers are used to depict the same or similar elements, features, and structures.

### DETAILED DESCRIPTION

Hereinafter, various example embodiments of the present disclosure will be described with reference to the accompanying drawings. Accordingly, those of ordinary skill in the art will recognize that modification, equivalent, and/or alternative on the various embodiments described herein can be variously made without departing from the scope and spirit of the present disclosure. With regard to description of drawings, similar components may be marked by similar reference numerals.

In the disclosure disclosed herein, the expressions “have”, “may have”, “include” and “comprise”, or “may include” and “may comprise” used herein indicate existence of corresponding features (for example, elements such as numeric values, functions, operations, or components) but do not exclude presence of additional features.

In the disclosure disclosed herein, the expressions “A or B”, “at least one of A or/and B”, or “one or more of A or/and B”, and the like used herein may include any and all combinations of one or more of the associated listed items. For example, the term “A or B”, “at least one of A and B”, or “at least one of A or B” may refer to all of the case (1) where at least one A is included, the case (2) where at least one B is included, or the case (3) where both of at least one A and at least one B are included.

The terms, such as “first”, “second”, and the like used herein may refer to various elements of various embodiments of the present disclosure, but do not limit the elements. For example, such terms are used only to distinguish an element from another element and do not limit the order and/or priority of the elements. For example, a first user device and a second user device may represent different user devices irrespective of sequence or importance. For example, without departing the scope of the present disclosure, a first element may be referred to as a second element, and similarly, a second element may be referred to as a first element.

It will be understood that when an element (for example, a first element) is referred to as being “(operatively or communicatively) coupled with/to” or “connected to” another element (for example, a second element), it can be directly coupled with/to or connected to the other element or an intervening element (for example, a third element) may be present. In contrast, when an element (for example, a first element) is referred to as being “directly coupled with/to” or “directly connected to” another element (for example, a second element), it should be understood that there are no intervening element (for example, a third element).

According to the situation, the expression “configured to” used herein may be used as, for example, the expression “suitable for”, “having the capacity to”, “designed to”, “adapted to”, “made to”, or “capable of”. The term “configured to (or set to)” must not mean only “specifically designed to” in hardware. Instead, the expression “a device configured to” may refer to a situation in which the device is “capable of” operating together with another device or other components. CPU, for example, a “processor configured to (or set to) perform A, B, and C” may refer, for example, to a dedicated processor (for example, an embedded processor) for performing a corresponding operation or a generic-purpose processor (for example, a central processing unit (CPU) or an application processor) which may perform corresponding operations by executing one or more software programs which are stored in a memory device.

Terms used in this disclosure are used to describe specified embodiments of the present disclosure and are not intended to limit the scope of the present disclosure. The terms of a singular form may include plural forms unless otherwise specified. Unless otherwise defined herein, all the terms used herein, which include technical or scientific terms, may have the same meaning that is generally understood by a person skilled in the art. It will be further understood that terms, which are defined in a dictionary and commonly used, should also be interpreted as is customary in the relevant related art and not in an idealized or overly formal detect unless expressly so defined herein in various embodiments of the present disclosure. In some cases, even if terms are terms which are defined in the disclosure, they may not be interpreted to exclude embodiments of the present disclosure.

An electronic device according to various example embodiments of the present disclosure may include at least one of smartphones, tablet personal computers (PCs), mobile phones, video telephones, electronic book readers, desktop PCs, laptop PCs, netbook computers, workstations, servers, personal digital assistants (PDAs), portable multimedia players (PMPs), MP3 players, mobile medical devices, cameras, and wearable devices, or the like, but is not limited thereto. According to various embodiments of the present disclosure, the wearable devices may include accessories (for example, watches, rings, bracelets, ankle bracelets, glasses, contact lenses, or head-mounted devices (HMDs)), cloth-integrated types (for example, electronic clothes), body-attached types (for example, skin pads or tattoos), or implantable types (for example, implantable circuits), or the like, but is not limited thereto.

In some embodiments of the present disclosure, the electronic device may be one of home appliances. The home appliances may include, for example, at least one of a digital video disk (DVD) player, an audio, a refrigerator, an air conditioner, a cleaner, an oven, a microwave oven, a washing machine, an air cleaner, a set-top box, a home automation control panel, a security control panel, a TV box (for example, Samsung HomeSync™, Apple TV™, or Google TV™), a game console (for example, Xbox™ or PlayStation™), an electronic dictionary, an electronic key, a camcorder, or an electronic panel, or the like, but is not limited thereto.

In another embodiment of the present disclosure, the electronic device may include at least one of various medical devices (for example, various portable medical measurement devices (a blood glucose meter, a heart rate measuring device, a blood pressure measuring device, and a body temperature measuring device), a magnetic resonance angiography (MRA), a magnetic resonance imaging (MRI) device, a computed tomography (CT) device, a photographing device, and an ultrasonic device), a navigation system, a global navigation satellite system (GNSS), an event data recorder (EDR), a flight data recorder (FDR), a vehicular infotainment device, electronic devices for vessels (for example, a navigation device for vessels and a gyro compass), avionics, a security device, a vehicular head unit, an industrial or home robot, an automatic teller's machine (ATM) of a financial company, a point of sales (POS) of a store, or an internet of things (for example, a bulb, various sensors, an electricity or gas meter, a spring cooler device, a fire alarm device, a thermostat, an electric pole, a toaster, a sporting apparatus, a hot water tank, a heater, and a boiler), or the like, but is not limited thereto.

According to some embodiments of the present disclosure, the electronic device may include at least one of a furniture or a part of a building/structure, an electronic board, an electronic signature receiving device, a projector, or various measurement devices (for example, a water service, electricity, gas, or electric wave measuring device), or the like, but is not limited thereto. In various embodiments of the present disclosure, the electronic device may be one or a combination of the aforementioned devices. The electronic device according to some embodiments of the present disclosure may be a flexible electronic device. Further, the electronic device according to an embodiment of the present disclosure is not limited to the aforementioned devices, but may include new electronic devices produced due to the development of technologies.

Hereinafter, electronic devices according to an embodiment of the present disclosure will be described with reference to the accompanying drawings. The term “user” used herein may refer to a person who uses an electronic device or may refer to a device (for example, an artificial electronic device) that uses an electronic device.

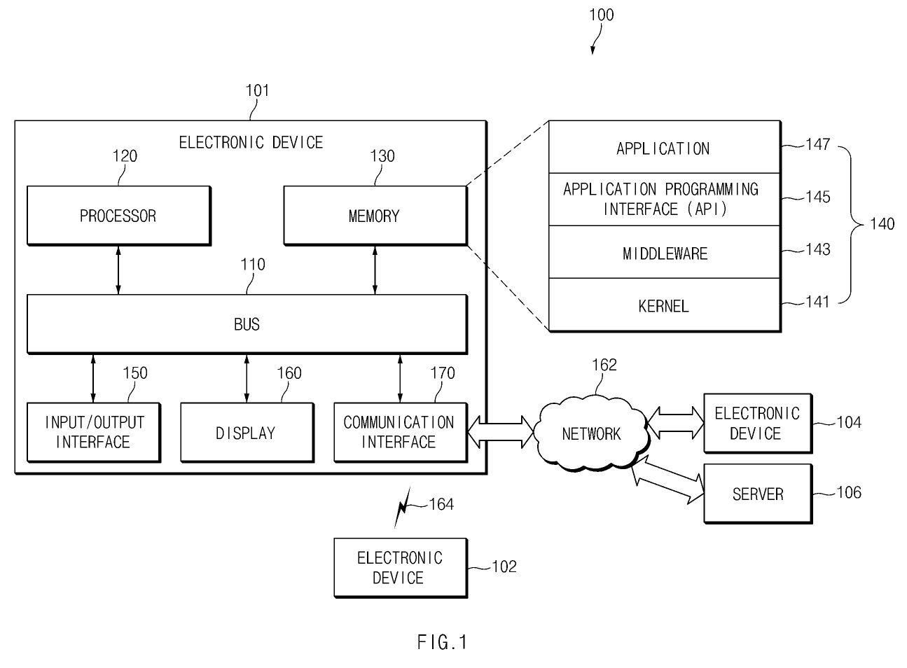

FIG. 1 is a diagram illustrating an example electronic device 101 in a network environment 100, according to various example embodiments.

Referring to FIG. 1, there is illustrated an electronic device 101 in a network environment 100 according to various embodiments. The electronic device 101 may include a bus 110, a processor 120, a memory 130, an input/output (I/O) interface (e.g., including input/output circuitry) 150, a display 160, and a communication interface (e.g., including communication circuitry) 170. According to an embodiment, the electronic device 101 may not include at least one of the above-described elements or may further include other element(s).

For example, the bus 110 may interconnect the above-described elements 120 to 170 and may include a circuit for conveying communications (e.g., a control message and/or data) among the above-described elements.

The processor 120 (e.g., the processor 110 of FIG. 1) may include one or more of a central processing unit (CPU), an application processor (AP), or a communication processor (CP). The processor 120 may perform, for example, data processing or an operation associated with control and/or communication of at least one other element(s) of the electronic device 101.

The memory 130 (e.g., the memory 160 of FIG. 1) may include a volatile and/or nonvolatile memory. For example, the memory 130 may store instructions or data associated with at least one other element(s) of the electronic device 101. According to an embodiment, the memory 130 may store software and/or a program 140. The program 140 may include, for example, a kernel 141, a middleware 143, an application programming interface (API) 145, and/or an application program (or “application”) 147. At least a part of the kernel 141, the middleware 143, or the API 145 may be called an “operating system (OS)”.

The kernel 141 may control or manage system resources (e.g., the bus 110, the processor 120, the memory 130, and the like) that are used to execute operations or functions of other programs (e.g., the middleware 143, the API 145, and the application program 147). Furthermore, the kernel 141 may provide an interface that allows the middleware 143, the API 145, or the application program 147 to access discrete elements of the electronic device 101 so as to control or manage system resources.

The middleware 143 may perform a mediation role such that the API 145 or the application program 147 communicates with the kernel 141 to exchange data.

Furthermore, the middleware 143 may process one or more task requests received from the application program 147 according to a priority. For example, the middleware 143 may assign the priority, which makes it possible to use a system resource (e.g., the bus 110, the processor 120, the memory 130, or the like) of the electronic device 101, to at least one of the application program 147. For example, the middleware 143 may process the one or more task requests according to the priority assigned to the at least one, which makes it possible to perform scheduling or load balancing on the one or more task requests.

The API 145 may be an interface through which the application 147 controls a function provided by the kernel 141 or the middleware 143, and may include, for example, at least one interface or function (e.g., an instruction) for a file control, a window control, image processing, a character control, or the like.

The I/O interface 150 may include various I/O circuitry configured to transmit an instruction or data, input from a user or another external device, to other element(s) of the electronic device 101. Furthermore, the I/O interface 150 may output an instruction or data, received from other element(s) of the electronic device 101, to a user or another external device.

The display 160 may include, for example, a liquid crystal display (LCD), a light-emitting diode (LED) display, an organic LED (OLED) display, or a microelectromechanical systems (MEMS) display, or an electronic paper display. The display 160 may display, for example, various kinds of content (e.g., a text, an image, a video, an icon, a symbol, and the like) to a user. The display 160 may include a touch screen and may receive, for example, a touch, gesture, proximity, or hovering input using an electronic pen or a portion of a user's body.

The communication interface 170 may include various communication circuitry configured to establish communication between the electronic device 101 and an external device (e.g., a first external electronic device 102, a second external electronic device 104, or a server 106). For example, the communication interface 170 may be connected to the network 162 through wireless communication or wired communication to communicate with the external device (e.g., the second external device 104 or the server 106).

The wireless communication may include at least one of, for example, LTE (long-term evolution), LIE-A (LTE Advance), CDMA (Code Division Multiple Access), WCDMA (Wideband CDMA), UMTS (Universal Mobile Telecommunications System), WiBro (Wireless Broadband), or GSM (Global System for Mobile Communications), or the like, as cellular communication protocol. Also, the wireless communication may include, for example, a local area network 164. The local area network 164 may include at least one of wireless fidelity (Wi-Fi), Bluetooth, near field communication (NFC), magnetic stripe transmission (MST), global navigation satellite system (GNSS), or the like.

The MST may generate a pulse corresponding to transmission data by using an electromagnetic signal, and the pulse may generate a magnetic field signal. The electronic device 101 may send the magnetic field signal to a point of sale (POS), and the POS may recover the data by detecting the magnetic field signal by using a MST reader and converting the detected magnetic field signal into an electrical signal.

The GNSS may include at least one of, for example, a global positioning system (GPS), a global navigation satellite system (Glonass), a Beidou Navigation Satellite System (hereinafter referred to as “Beidou”), or a European global satellite-based navigation system (Galileo), based on a use area or bandwidth. Hereinafter, in this disclosure, “GPS” and “GNSS” may be interchangeably used. The wired communication may include at least one of, for example, a universal serial bus (USB), a high definition multimedia interface (HDMI), a recommended standard 232 (RS-232), a plain old telephone service (POTS), or the like. The network 162 may include at least one of telecommunications networks, for example, a computer network (e.g., LAN or WAN), an Internet, or a telephone network.

According to various embodiments, the communication interface 170 includes a communication module comprising communication circuitry that connects to any one of the wired communication network and the wireless communication module according to communication standard and protocol and performs a function that connects a communication channel with a server (or device) or any other augmented reality device through the communication network. The communication interface 170 may send requirements of a user input processed by the processor 120 to any other device and may share the requirements.

According to various embodiments, the communication interface 170 may include various communication circuitry configured to process signals of multiple frequency bands. The communication interface 170 may include various communication circuitry, such as, for example, and without limitation, at least one antenna and may send and receive signals of the multiple frequency bands to and from an external device through the antenna.

According to various embodiments, in the case where the communication circuitry of the communication interface 170 receives signals of the multiple frequency bands from the external device, the communication interface 170 may classify or group the signals included in the respective frequency bands, for each frequency band. Also, if necessary, the communication interface 170 may filter or amplify signals included in the multiple frequency bands.

In various embodiments, the communication interface 170 may include communication circuitry configured to send and receive signals that are based on a carrier aggregation (CA) technology. The carrier aggregation (CA) technology may be a technology of bundling a plurality of frequency bands so as to be used as one frequency band. The CA technology may efficiently combine limited frequency resources to improve a speed at which data is sent and received.

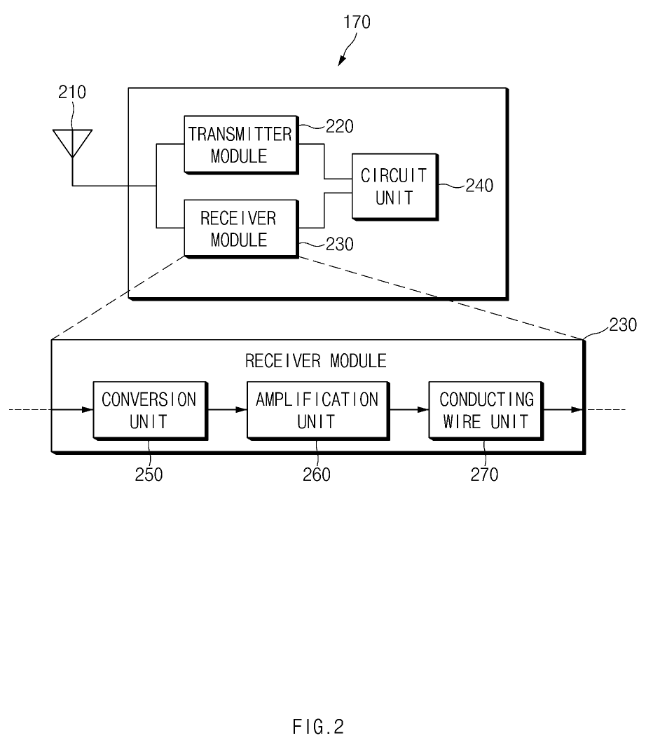

In various embodiments, the communication interface 170 may include circuitry configured to selectively switch at least some of communication bands that are combined according to the CA technology and may amplify the switched communication bands. Accordingly, the communication interface 170 may reduce the number of amplifiers to be used and may reduce the number of signal lines through which the signals are transferred to a circuit unit (e.g., RF IC). Additional information about the communication interface 170 may be provided through FIGS. 2 to 8.

Each of the first and second external electronic devices 102 and 104 may be a device of which the type is different from or the same as that of the electronic device 101. According to an embodiment, the server 106 may include a group of one or more servers. According to various embodiments, all or a portion of operations that the electronic device 101 will perform may be executed by another or plural electronic devices (e.g., the electronic devices 102 and 104 or the server 106). According to an embodiment, in the case where the electronic device 101 executes any function or service automatically or in response to a request, the electronic device 101 may not perform the function or the service internally, but, alternatively additionally, it may request at least a part of a function associated with the electronic device 101 at other device (e.g., the electronic device 102 or 104 or the server 106). The other electronic device (e.g., the electronic device 102 or 104 or the server 106) may execute the requested function or additional function and may transmit the execution result to the electronic device 101. The electronic device 101 may provide the requested function or service using the received result or may additionally process the received result to provide the requested function or service. To this end, for example, cloud computing, distributed computing, or client-server computing may be used.

FIG. 2 is a block diagram illustrating an example communication interface, according to various example embodiments.

Referring to FIG. 2, the communication circuit 170 may include various communication circuitry, including, for example, and without limitation, an antenna 210, a transmitter module (e.g., including transmitting circuitry) 220, a receiver module (e.g., including receiver circuitry) 230, and a circuit unit (e.g., including circuitry configured to process a signal) 240. The transmitter module 220 and the receiver module 230 are only separated according to a function. However, the transmitter module 220 and the receiver module 230 may be implemented to share some elements or may be implemented in the form of a chip.

The antenna 210 may transmit a signal, which the electronic device 101 processes through the transmitter module 220, to an external device (e.g., the electronic device 102 or 104 or the server 106 of FIG. 1) over a network. Also, the antenna 210 may receive signals (e.g., RF signals) of various frequency bands from the external device. The received signal may be provided to the circuit unit 240 (e.g., RF IC) after being processed through the receiver module 230.

The transmitter module 220 may include transmitting circuitry configured to transmit a signal to the external device through the antenna 210. The transmitter module 220 may amplify or convert a data signal from the circuit unit 240 to generate a transmission signal suitable for a communication environment of the network.

The receiver module 230 may include circuitry configured to convert a signal received through the antenna 210 through circuitry configured to perform classification, filtering, amplification, and the like and may provide the converted data signal to the circuit unit 240. In various embodiments, the receiver module 230 may receive signals of multiple frequency bands from the external device (e.g., the electronic device 102 or 104 or the server 106).

According to various embodiments, the receiver module 230 may include circuitry configured to classify and group signals, which are included in frequency bands that the circuit unit 240 can process, from among the received signals. The receiver module 230 may include circuitry configured to amplify signals included in respective groups in different manners and may provide the amplified signals to the circuit unit 240. The receiver module 230 may include circuitry configured to selectively connect at least one group to an amplifier through a switch, thereby reducing the number of amplifiers to be implemented and the number of signal lines to be implemented.

According to an embodiment, the receiver module 230 may include a conversion unit (e.g., including conversion circuitry) 250, an amplification unit (e.g., including amplification circuitry) 260, and a conducting wire unit (e.g., including conducting wires) 270.

The conversion unit 250 may include conversion circuitry configured to classify or group signals of multiple frequency bands received through the antenna 210 into specified bands. Whether to filter, a kind of a filter to be used, a way to amplify, and the like may vary according to the classified bands or groups.

According to various embodiments, the conversion unit 250 may classify signals of multiple frequency bands into two bands based on a frequency. For example, the conversion unit 250 may classify signals of the multiple frequency bands into a low band and a middle/high band. Alternatively, the conversion unit 250 may classify signals of the multiple frequency bands into three bands, that is, a low band, a middle band, and a high band. The low band may be a frequency band of 1.5 GHz or lower. The middle band may be a band from 1.5 to 2.2 GHz. The high band may be a band from 2.3 to 6 GHz.

According to various embodiments, the conversion unit 250 may include a filter that corresponds to each frequency included in the multiple frequency bands. The conversion unit 250 may remove a noise signal through the filter and may classify signals of the multiple frequency bands based on frequency bands.

According to various embodiments, the conversion unit 250 may classify signals included in respective bands into a plurality of groups based on an amplification manner. At least some of the plurality of groups may be selectively connected with an amplifier through a switch (e.g., may be connected to a low noise amplifier (LNA) through a multiplexer).

In various embodiments, a first communication band and a second communication band that are combined according to the CA technology may be allocated to different groups. For example, the first communication band may be allocated to a first group, and the second communication band may be allocated to a second band. The first communication band and the second communication band may be transmitted to the circuit unit 240 after being amplified by the amplification unit 260 in different manners. For example, the first communication band may be amplified through a first LNA amplifier without separate switching, and the second communication band may be amplified by a second LNA amplifier that is selectively connected through a switch.

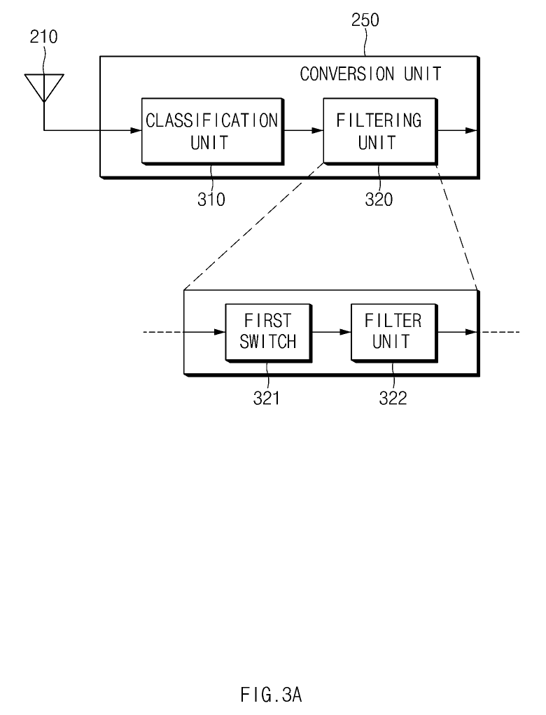

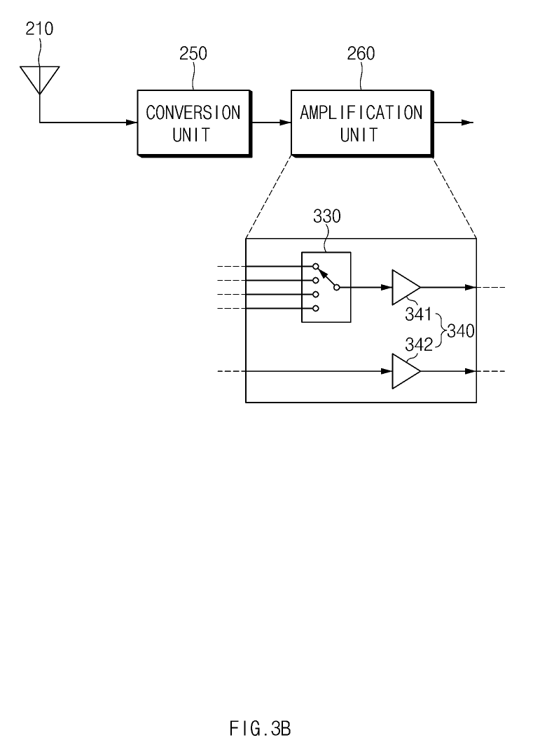

Additional information about the conversion unit 250 may be provided below with reference to FIG. 3A.

The amplification unit 260 may include circuitry configured to amplify a signal converted through the conversion unit 250. A distance between the conversion unit 250 and the circuit unit 240 may be relatively long in the interior of the electronic device 101. In this case, since the intensity of signal becomes weak when the signal is transferred to the circuit unit 240 through the conducting wire unit 270, it may be difficult for the circuit unit 240 to recognize the signal or the circuit unit 240 may recognize the signal abnormally. The amplification unit 260 may amplify a signal to compensate for power loss occurring while passing through the conducting wire unit 270.

According to various embodiments, the amplification unit 260 may amplify signals in different manners based on a band or group classified by the conversion unit 250. For example, the amplification unit 260 may amplify a signal included in the first group without separate switching. In contrast, the amplification unit 260 may selectively amplify a signal included in the second group through switching (e.g., may amplify only a signal of a frequency band selected through switching). Additional information about the amplification unit 260 may be provided through FIG. 3B.

The conducting wire unit 270 may include wires or wiring configured to transfer a signal amplified through the amplification unit 260 to the circuit unit 240. The conducting wire unit 270 may include physical wiring lines for transferring electrical signals. For example, the conducting wire unit 270 may include conducting wires arranged on a printed circuit board.

According to various embodiments, the conducting wire unit 270 may include a plurality of signal lines the number of which is less than the number of multiple frequency bands that the circuit unit 240 processes. For example, in the case where the circuit unit 240 processes signals of first to tenth bands, the conducting wire unit 270 may be implemented with three signal lines. In various embodiments, signals that are combined according to the CA technology may be transmitted through different signal lines. For example, in the case where the first communication band and the second communication band are combined, the first communication band may be transmitted through a first signal line and the second communication band may be transmitted through a second signal line.

In general, an amplifier and a signal line are implemented to be connected to each other for each frequency band. In this case, as the number of frequency bands increases, the number of amplifiers and the number of signal lines may increase, and thus a mounting space may be limited. Also, the increase of signal lines may cause interference with peripheral chips or modules.

In contrast, according to embodiments, signals of multiple frequency bands may be grouped such that the signals of the multiple frequency bands are amplified in different manners for respective groups. As such, it may be possible to reduce the number of amplifiers and the number of signal lines and to transmit and process signals of the multiple frequency bands efficiently within a limited mounting space.

The circuit unit 240 may include circuitry configured to process signals included in the multiple frequency bands. With regard to various frequency bands, the circuit unit 240 may allow the electronic device 101 to efficiently cope with various network environments. In various embodiments, the circuit unit 240 may be formed to be independent of the processor 120 of FIG. 1 or may be implemented in the form of a module included in the processor 120.

The receiver module 230 is illustrated in FIG. 2 as operatively including the conducting wire unit 270. However, embodiments are not limited thereto. For example, the conducting wire unit 270 may be an element that is independent of the receiver module 230. The conducting wire unit 270 may include signal lines that connect the receiver module 230 and the circuit unit 240 each of which is formed with one chip.

FIG. 3A is a block diagram illustrating an example configuration of a conversion unit, according to various example embodiments.

Referring to FIG. 3A, the conversion unit 250 may include a classification unit (e.g., including classification circuitry) 310 and a filtering unit (e.g., including filtering circuitry, such as, for example, a filter) 320.

The classification unit 310 may include circuitry configured to classify signals of multiple frequency bands received through the antenna 210, based on specified bands. The bands may be set in advance or may be determined according to a frequency distribution range of received signals. For example, the classification unit 310 may classify signals received through the antenna 210 into two or three specified bands. The classified signals may be transferred to the circuit unit 240 through different signal lines after being amplified through different amplifiers.

The filtering unit 320 may include various circuitry configured to filter a signal of a frequency band included in each band classified through the classification unit 310. The filtering unit 320 may remove a noise signal included in each signal, and the filtering unit 320 may separate signals of the multiple frequency bands based on frequency bands. In various embodiments, the filtering unit 320 may include a first switch 321 and a filter unit 322.

The first switch 321 may include switching circuitry configured to select the filter unit 322 corresponding to a signal of each frequency band such that an output of the classification unit 310 and an input of the filter unit 322 are connected to each other. For example, in the case where an electronic device supports four frequency bands in the high band, the first switch 321 may connect the output of the classification unit 310 and the input of the filter unit 322 corresponding to each band, by using an SP4T (single pole 4 throw) switch.

The filter unit 322 may include a plurality of filters that correspond respectively to frequency bands that the electronic device 101 receives. For example, in the case where a first filter passes a signal of a B2 (1.8 GHz) band, signals of the remaining frequency bands other than the B2 (1.8 GHz) band may be removed. Also, the filter unit 322 may remove unnecessary signals included in each signal, such as a noise signal and the like.

Signals that pass through the filter unit 322 may be amplified by the amplification unit 260 after being grouped into a plurality of groups. In various embodiments, the signals may be amplified in different manners for respective groups.

FIG. 3B is a block diagram illustrating an example configuration of an amplification unit (e.g., including amplification circuitry) 260, according to various example embodiments.

Referring to FIG. 3B, the amplification unit 260 may include circuitry configured to receive signals that are classified and filtered through the conversion unit 250. The amplification unit 260 may include various circuitry, such as, for example, amplifiers, to amplify some signals received through the conversion unit 250 by using a switch 330 and a first amplifier 341 and may amplify the remaining signal(s) by using a second amplifier 342.

In various embodiments, the switch 330 may select one of a plurality of communication bands that are different from each other. The switch 330 may be controlled by the circuit unit 240 (or the processor 120) included in the electronic device 101. The electronic device 101 may select a necessary communication band based on a communication environment, and a signal included in the selected communication band may be transferred to the circuit unit 240 after being amplified.

The first amplifier 341 may amplify a signal of a filter that is selected and connected through the switch 330. The amplified signal may be transmitted to the circuit unit 240 through the conducting wire unit 270. The first amplifier 341 may compensate for a loss of a signal passing through the conducting wire unit 270. In various embodiments, the switch 330 and the first amplifier 341 may be implemented with one module or chip.

The second amplifier 342 may amplify a signal output through the conversion unit 250 without separate switching. A signal to be amplified through the second amplifier 342 may be determined in consideration of a communication environment or a design environment. In various embodiments, the first amplifier 341 may amplify a signal of the first communication band, and the second amplifier 342 may amplify a signal of the second communication band which is combined with the first communication band through the carrier aggregation.

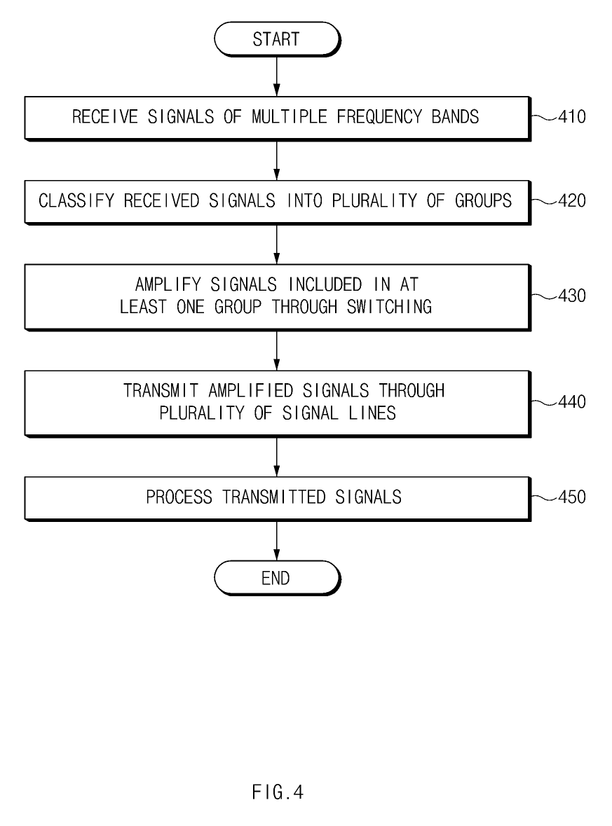

FIG. 4 is a flowchart illustrating an example signal processing method, according to various example embodiments.

Referring to FIG. 4, in operation 410, the antenna 210 may receive signals of multiple frequency bands. The received signals may be provided to the circuit unit 240 through the receiver module 230.

In operation 420, the conversion unit 250 may classify the signals received through the antenna 210 into a plurality of groups. The receiver module 230 may classify the received signals into a plurality of groups, based on amplification manners. Signals to be allocated to the respective groups may vary according to a relevant communication service environment in the electronic device 101.

For example, a first signal may be allocated to a first group, and a second signal to a fifth signal may be allocated to a second group. First and second frequency bands (e.g., CA signals) may be signals with relatively high use possibility or frequency, and third to fifth frequency bands (e.g., loaming signals) may be signals with relatively low use possibility or frequency.

In operation 430, the amplification unit 260 may amplify signals included in at least one of the plurality of groups through switching (e.g., amplification through a multiplexer and an LNA). For example, the amplification unit 260 may select one of signals included in one group through the multiplexer and may connect the selected signal to an input of an amplifier. In this case, other unselected signals may not be connected to the conducting wire unit 270 and the circuit unit 240 as well as the amplifier. In various embodiments, signals belonging to other groups of the plurality of groups may be connected to the circuit unit 240 through the conducting wire unit 270 after being amplified (e.g., through the LNA) without separate switching. In various embodiments, signals of two or more frequency bands that are combined according to the CA technology may be allocated to different groups so as to be amplified in different manners.

In operation 440, the conducting wire unit 270 may transmit the amplified signals to the circuit unit 240 through a plurality of signal lines. In various embodiments, the conducting wire unit 270 may include only signal lines the number of which corresponds to the number of signals amplified through the amplification unit 260. In various embodiments, the conducting wire unit 270 may include signal lines the number of which is the same as the number of amplifiers included in the amplification unit 260.

In operation 450, the circuit unit 240 (e.g., RF IC) may process signals transmitted through the conducting wire unit 270. The circuit unit 240 may include various circuitry configured to extract data to be transmitted from each signal by converting/analyzing the transferred signals. In various embodiments, the circuit unit 240 may provide the extracted data to the processor 120 included in the electronic device 101.

According to various embodiments, a signal processing method performed by an electronic device, the method may include receiving signals of multiple frequency bands through an antenna, classifying the signals into a plurality of groups, selectively connecting signals, which belong to at least one of the plurality of groups, with an amplifier through a switch, transmitting amplified signals to a circuit unit through a plurality of signal lines and processing, at the circuit unit, the transmitted signals.

According to various embodiments, the classifying of the signals into the plurality of groups includes classifying the signals into a first band and a second band. The classifying of the signals into the plurality of groups includes classifying the first band as a first group or a second group and classifying the signal as a third group.

According to various embodiments, the selectively connecting of the signals includes amplifying the first group through a first amplifier and connecting the second group to a second amplifier through switching to amplify the second group. The selectively connecting of the signals includes connecting the third group to a third amplifier through switching to amplify the third group.

According to various embodiments, the classifying of the first band as the first group or the second group includes allocating a first communication band to the first group and allocating a second communication band, which is combined with the first communication band according to a carrier aggregation technology, to the second group. The classifying of the first band as the first group or the second group includes filtering the first communication band and the second communication band using, for example, a dual-SAW filter.

According to various embodiments, the transmitting includes transmitting the amplified signals to the circuit unit through a plurality of signal lines the number of which is less than the number of the multiple frequency bands.

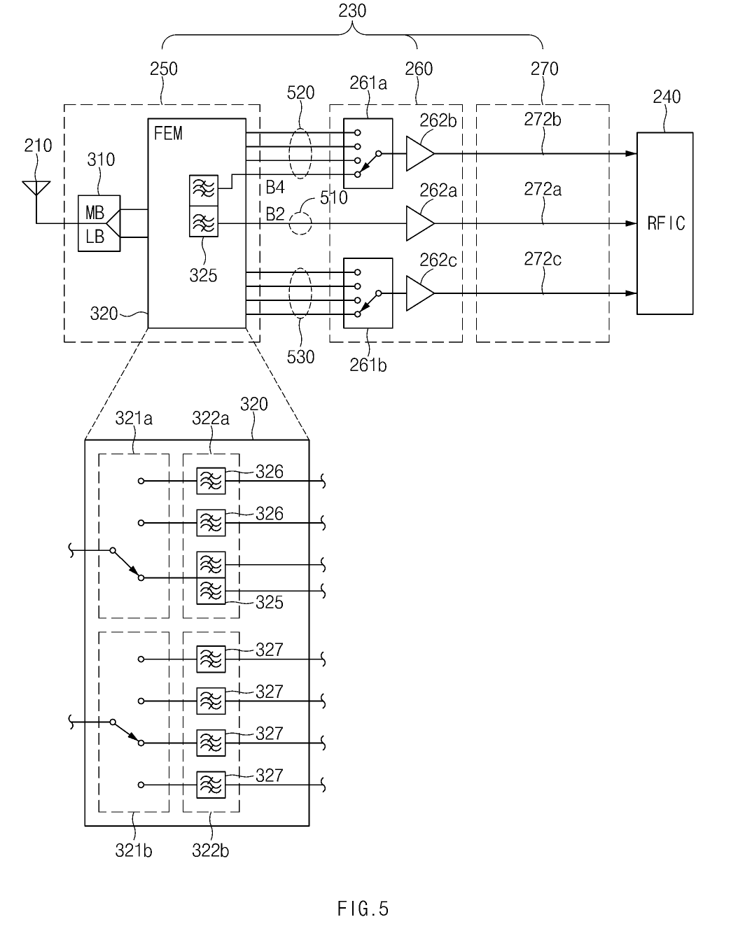

FIG. 5 is a diagram illustrating an example implementation of a communication interface, according to various example embodiments. FIG. 5 merely illustrates an example implementation, but is not limited thereto.

Referring to FIG. 5, the communication circuit 170 may include the antenna 210, the receiver module 230, and the circuit unit 240. The receiver module 230 may include the conversion unit 250, the amplification unit 260, and the conducting wire unit 270. The conversion unit 250 may include the classification unit 310 and the filtering unit 320.

The antenna 210 may receive signals of multiple frequency bands from an external device. The classification unit 310 may classify signals received through the antenna 210, based on specified bands. The bands may be set in advance or may be determined according to a frequency distribution range of received signals.

According to various embodiments, the classification unit 310 may classify the received signals into two or three bands. In various embodiments, the classification unit 310 may be implemented with a diplexer or triplexer. The classification unit 310 is illustrated in FIG. 5 as classifying signals of multiple frequency bands into the middle band and the low band. However, embodiments are not limited thereto.

The filtering unit 320 may filter a signal included in each of the classified bands. In various embodiments, the filtering unit 320 may be implemented with one front end module (FEM) chip. The filtering unit 320 may separate and filter frequency signals included in respective bands through a switch and a filter.

In various embodiments, the filtering unit 320 may include a dual surface acoustic wave (dual-SAW) filter 325. The dual-SAW filter 325 may be a kind of duplexer. The dual-SAW filter 325 may filter a first communication band (e.g., B2) and a second communication band (e.g., B4) that are combined according to the CA technology. The filtered first communication band (e.g., B2) may be amplified through a first amplifier 262a without separate switching. In contrast, the filtered second communication band (e.g., B4) may be selectively amplified through a second switch 261a and a second amplifier 262b.

According to various embodiments, the filtering unit 320 may include first and second switches 321a and 321b and a plurality of filters 322a and 322b.

The first and second switches 321a and 321b may select a filter, which corresponds to a signal of each frequency band, from among the plurality of filters 322a and 322b and may connect the selected filter to an output of the classification unit 310. In various embodiments, the first switch 321a and 321b may be implemented with an SPXT (e.g., SP3T or SP4T) switch.

For example, the first switch 321a may connect first and second signals, which are combined by the CA technology, from among first to fourth signals belonging to the middle band to the dual-SAW filter 325 and may connect the third and fourth signals to band-pass filters (BPF) 326, respectively. The second switch 321b may connect fifth to eighth signals belonging to the low band to band-pass filters (BPF) 327, respectively.

The plurality of filters 322a and 322b may remove unnecessary signals (e.g., noise signals) included in frequency signals and may pass signals of frequency bands specified for respective filters 322a and 322b. Signals passing through the plurality of filters 322a and 322b may be grouped and may then be amplified by the amplification unit 260.

In the above example, the first and second signals that are combined by the CA technology may be allocated to different groups after passing through the dual-SAW filter 325. As the first signal is allocated to a first group 510, the first signal may be transmitted to the circuit unit 240 through a first signal line 272a after being amplified through the first amplifier 262a without separate switching. In contrast, the second signal may be allocated to a second group 520 together with the third signal and the fourth signal. The second signal to the fourth signal may be selectively connected with a second amplifier 262b so as to be amplified. One of the first to fourth signals may be transmitted to the circuit unit 240 through a second signal line 272b.

According to various embodiments, some frequency bands may be processed without separate filters. In the above example, the first signal and the second signal may pass through the dual-SAW filter 325, and the third signal and the fourth signal may be connected to the amplification unit 260 without connection with separate filters.

The amplification unit 260 may include a third switch 261a, a fourth switch 261b, and first to third amplifiers 262a to 262c. The amplification unit 260 may amplify a signal of the first group 510 through the first amplifier 262a without separate switching. In various embodiments, the signal (e.g., B2) of the first group 510 may be a signal of which the use possibility or frequency is higher than that of another signal belonging to another group.

The amplification unit 260 may amplify a signal of the second group 520 through the third switch 261a and the second amplifier 262b. For example, a signal (e.g., B4) of the second group 520 may be transmitted to the circuit unit 240 through the second signal line 272b. In various embodiments, the signal (e.g., B4) of the second group 520 may be a signal of which the use possibility or frequency is higher than that of another signal belonging to the second group 520.

The amplification unit 260 may selectively amplify signals 530 (signals of a third group) belonging to the second band (e.g., the low band) through the fourth switch 261b and the third amplifier 262c. For example, one of signals 530 belonging to the second band may be transmitted to the circuit unit 240 through the third signal line 272c.

The conducting wire unit 270 may transmit a signal amplified through the amplification unit 260 to the circuit unit 240. In various embodiments, the number of the signal lines 272a to 272c constituting the conducting wire unit 270 may be less than the number of multiple frequency bands (e.g., a first frequency band to a ninth frequency band) that the receiver module 250 receives. The receiver module 230 may classify or group signals of multiple frequency bands received through the antenna 210 and may transfer the received signals to the circuit unit 240 through the relatively small number of amplifiers and the relatively small number of signal lines. As the small number of signal lines is used within a limited mounting space, the mounting efficiency may be improved and the interference with peripheral components may be reduced.

In a conventional case, an amplifier and a signal line are needed for respective signals included in multiple frequency bands, thereby causing a decrease of efficiency of mounting components. Also, since some signals are transferred without amplification due to a limited mounting space, a signal transfer characteristic may become worse.

FIG. 5 is not limited to the above example. For example, the signals 530 belonging to the second band (e.g., the low band) may be additionally grouped. In this case, some of grouped signals may be amplified without separate switching, and the remaining grouped signals may be selectively connected with an amplifier through a switch. Implementation may be possible in various forms according to a design environment or a communication environment.

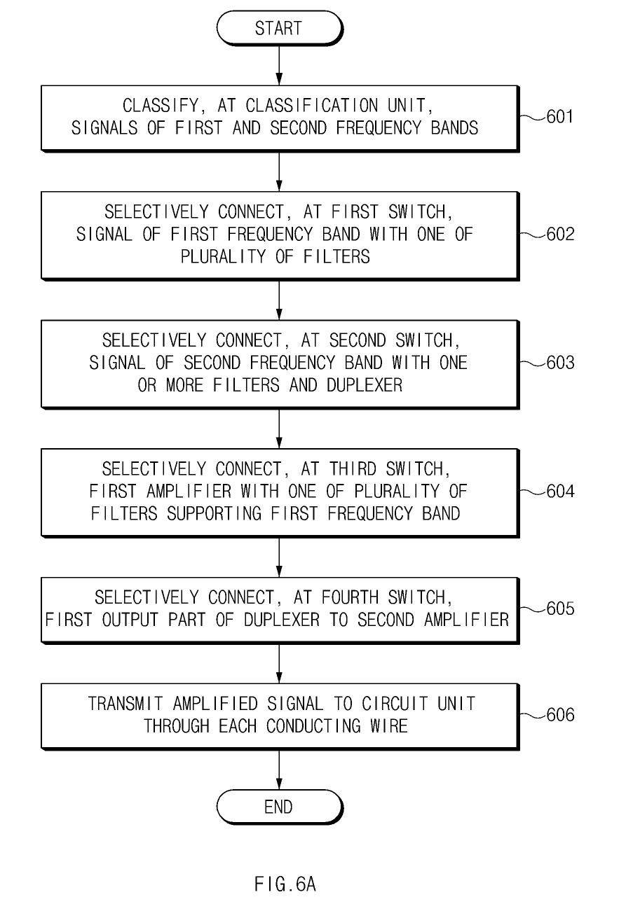

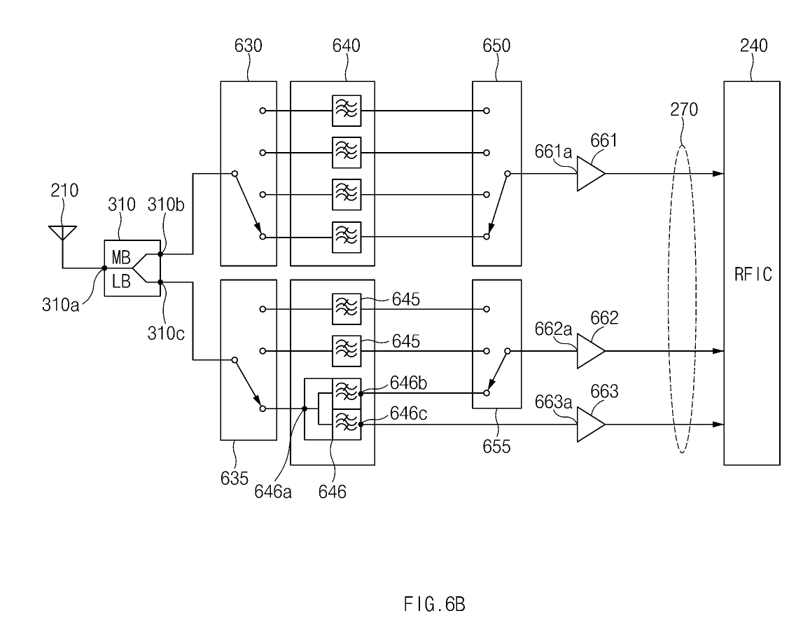

FIG. 6A is a flowchart illustrating an example method of receiving signals of a plurality of communication bands that are combined, according to various example embodiments.

Referring to FIG. 6A, in operation 601, the classification unit 310 may separate signals of first and second frequency bands received through the antenna 210. An input part of the classification unit 310 may be connected to the antenna 210, and a plurality of output parts thereof may be connected to switches, respectively. Below, it is assumed that two output parts (a first output part and a second output part) of the classification unit 310 are connected to first and second switches. However, embodiments are not limited thereto.

In operation 602, the first switch may selectively connect a plurality of filters, which support the first frequency band, with the first output part of the classification unit 310 from which the received signal of the first frequency band is output. Each of the plurality of filters may remove a noise signal and may pass a signal of a specified frequency band.

In operation 603, the second switch may selectively connect an input part of a duplexer and one or more filters, which support the second frequency band, with the second output part of the classification unit 310 from which the received signal of the second frequency band is output. Each of the one or more filters may remove a noise signal and may pass a signal of a specified frequency band. The duplexer may receive some of signals of the second frequency band. In various embodiments, some signals may be signals included in two communication bands (the first communication band and the second communication band) that are combined by the CA technology. The duplexer may separate and filter signals of the two communication bands.

In operation 604, the third switch may selectively connect an input part of the first amplifier with a plurality of filters that support the first frequency band. A signal selected through the third switch may be amplified, and an unselected signal may be blocked. In various embodiments, the third switch may pass a signal of a third communication band that is combined with the two communication bands (the first communication band and the second communication band) passing through the duplexer.

In operation 605, the fourth switch may selectively connect a first output part of the duplexer with an input part of the second amplifier. A signal selected through the fourth switch may be amplified, and an unselected signal may be blocked.

In operation 606, first to third amplifiers may transmit the amplified signals to the circuit unit 240 through conducting wires (or signal lines), respectively. The third switch and the fourth switch may make it possible to reduce amplifiers and conducting wires, which are applied to the receiver module 230, in number. This may mean that a space for mounting components is secured and the communication performance is improved.

FIG. 6B is a diagram illustrating an example communication interface that receives signals included in a plurality of communication bands, according to various example embodiments.

Referring to FIG. 6B, the first antenna 210 may receive signals of a first frequency band (e.g., the middle band) and a second frequency band (e.g., the low band) from another device.

The classification unit 310 may separate the signals of the first and second frequency bands received through the first antenna 210. An input part (a first port) 310a of the classification unit 310 may be connected to the first antenna 210. A first output part (a second port) (310b) of the classification unit 310 may be connected to a first switch 630, and the signal of the first frequency band may be output from the first output part 310b of the classification unit 310. A second output part (a second port) (310c) of the classification unit 310 may be connected to a second switch 635, and the signal of the second frequency band may be output from the second output part 310b of the classification unit 310.

The first switch 630 may selectively connect the first output part 310b of the classification unit 310 with a plurality of filters 640 supporting the first frequency band. Each of the plurality of filters 640 may remove a noise signal and may pass a signal of a specified frequency band. The plurality of filters 640 are illustrated in FIG. 6B as including four filters. However, embodiments are not limited thereto.

The second switch 635 may selectively connect the second output part 310c of the classification unit 310 with an input part (first port) 646a of the duplexer 646 and one or more filters 645 supporting the second frequency band. Each of the one or more filters 645 may remove a noise signal and may pass a signal of a specified frequency band. The one or more filters 645 are illustrated in FIG. 6B as including two filters. However, embodiments are not limited thereto.

The input part (first port) 646a of the duplexer 646 may be connected to the second switch 635 to receive some of signals of the second frequency band. In various embodiments, some signals may be signals included in two communication bands that are combined by the CA technology. The duplexer 646 may separate and filter signals of the two communication bands. In various embodiments, the duplexer 646 may be implemented with a dual-SAW filter. A first output part (second port) 646b of the duplexer 646 may output a signal of the first communication band, and a second output part (third port) 646c of the duplexer 646 may output a signal of the second communication band.

A third switch 650 may selectively connect the plurality of filters 640, which support the first frequency band, with an input part 661a of a first amplifier 661. A signal selected through the third switch 650 may be amplified through the first amplifier 661. In various embodiments, the plurality of filters 640 and the third switch 650 may pass a signal of the third communication band (combined by the CA technology with the first communication band and the second communication band passing through the duplexer 646).

A fourth switch 655 may selectively connect a first output part 646b of the duplexer 646 with an input part 662a of a second amplifier 662. In various embodiments, the first output part 646b of the duplexer 646 may output a signal of the first communication band by the carrier aggregation. The fourth switch 655 may selectively output the signal of the first communication band and other signals passing through one or more filters 645.

A second output part 646c of the duplexer 646 may output a signal of the second communication band by the carrier aggregation and may be connected to an input part 664 of a third amplifier 663.

Each of the first to third amplifiers 661 to 663 may amplify a signal received through an input part thereof. In various embodiments, the first to third amplifiers 661 to 663 may respectively amplify and output signals of the first to third communication bands combined by the carrier aggregation.

The conducting wire unit 270 may transmit the signals amplified through the first to third amplifiers 661 to 663 to the circuit unit (e.g., RF IC or a transceiver) 240. In various embodiments, the number of conducting wires (or signal lines) constituting the conducting wire unit 270 may be the same as the number of communication bands combined by the carrier aggregation.

The circuit unit (e.g., RF IC or the transceiver) 240 may process signals transmitted through the conducting wire unit 270. In various embodiments, the circuit unit 240 may process downlink signals of three communication bands that are combined by the CA technology. In various embodiments, the circuit unit 240 may be connected to a second antenna (not illustrated) that is distinguished from the first antenna 210. The second antenna (not illustrated) may receive a signal of the second frequency band and may transfer the received signal to the circuit unit 240. In various embodiments, a distance between the first antenna 210 and the circuit unit 240 may be larger than a distance between the second antenna (not illustrated) and the circuit unit 240.

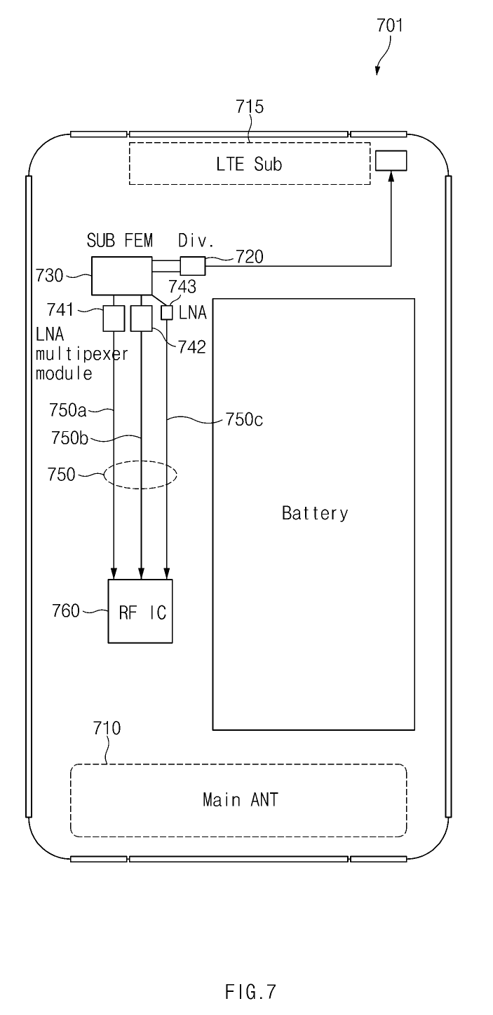

FIG. 7 is a diagram illustrating an example configuration of an electronic device, according to various example embodiments. FIG. 7 is merely an example implementation, but is not limited thereto.

Referring to FIG. 7, an electronic device 701 may send and receive signals to and from an external device by using a first antenna 710 and a second antenna 715. The first antenna 710 may be a main antenna of the electronic device 701, and the second antenna 715 may be a sub antenna thereof.

In various embodiments, a circuit unit (e.g., RF IC) 760 that processes signals received from the external device may be arranged adjacent to the main antenna, that is, the first antenna 710. Within the electronic device 701, a distance between the sub antenna, that is, the second antenna 715 and the circuit unit 760 may be larger than a distance between the first antenna 710 and the circuit unit 760.

A signal received through the second antenna 715 may be transferred to the circuit unit 760 through a classification unit 720, a filtering unit 730, and a conducting wire unit 750. In this case, to prevent and/or avoid a signal from being lost upon transmission of the signal through the conducting wire unit 750, the signal may be transmitted after being amplified through an amplification unit (e.g., LNA multiplexer modules 741 and 742 and an LNA 743).

According to various embodiments, the conducting wire unit 750 may include signal lines the number of which is less than the number of multiple frequency bands that the second antenna 715 receives. Accordingly, it may be possible to secure a space for arranging signal lines and to reduce the interference with peripheral components.

For example, the electronic device 701 may group multiple frequency bands by using the LNA multiplexer modules 741 and 742 in which a multiplexer and an LNA are combined. The electronic device 701 may select only one signal from one group and may transfer the selected signal to the circuit unit 760 through a connected signal line 750a or 750b. Also, the electronic device 701 may amplify a signal with a relatively high use possibility or frequency through the LNA 743 without separate switching and may transfer the amplified signal to the circuit unit 760 through a connected signal line 750c.

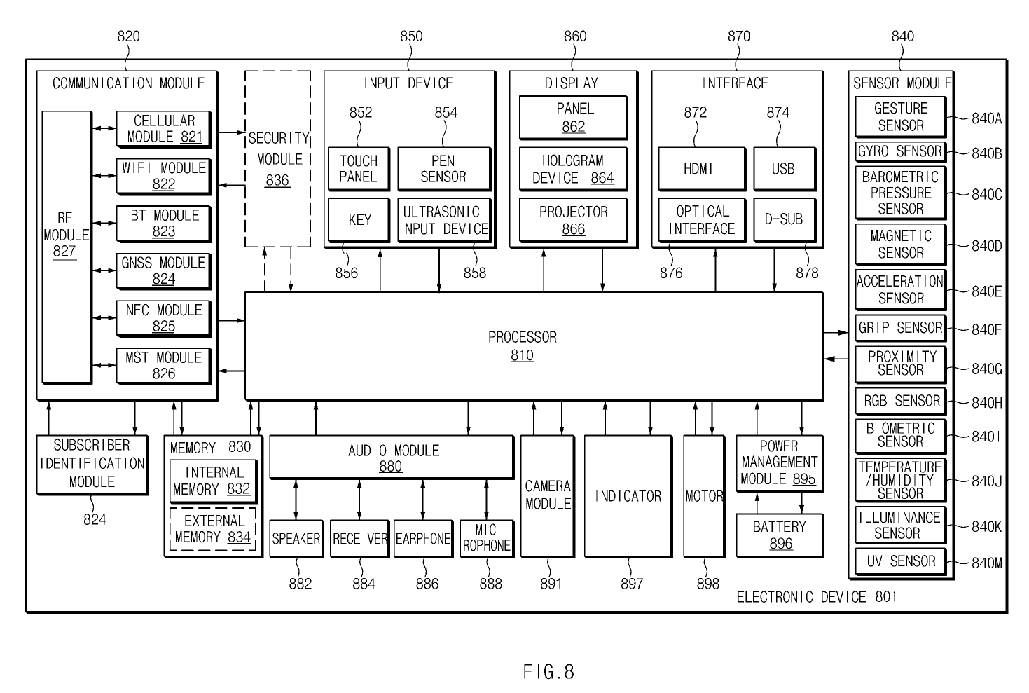

FIG. 8 is a block diagram illustrating an example electronic device according to various example embodiments. An electronic device 801 may include, for example, all or a part of the electronic device 101 illustrated in FIG. 1. The electronic device 801 may include one or more processors (e.g., an application processor (AP)) 810, a communication module (e.g., including communication circuitry) 820, a subscriber identification module 824, a memory 830, a sensor module 840, an input device (e.g., including input circuitry) 850, a display 860, an interface (e.g., including interface circuitry) 870, an audio module 880, a camera module 891, a power management module 895, a battery 896, an indicator 897, and a motor 898.

The processor 810 may drive an operating system (OS) or an application to control a plurality of hardware or software elements connected to the processor 810 and may process and compute a variety of data. The processor 810 may be implemented with a System on Chip (SoC), for example. According to an embodiment, the processor 810 may further include a graphic processing unit (GPU) and/or an image signal processor. The processor 810 may include at least a part (e.g., a cellular module 821) of elements illustrated in FIG. 8. The processor 810 may load and process an instruction or data, which is received from at least one of other elements (e.g., a nonvolatile memory) and may store a variety of data in a nonvolatile memory.

The communication module 820 may include various communication circuitry and be configured the same as or similar to the communication interface 170 of FIG. 1. The communication module 820 may include various communication circuitry, such as, for example, and without limitation, a cellular module 821, a Wi-Fi module 823, a Bluetooth (BT) module 825, a GNSS module 827 (e.g., a GPS module, a Glonass module, a Beidou module, or a Galileo module), a near field communication (NFC) module 828, and a radio frequency (RF) module 829.

The cellular module 821 may provide voice communication, video communication, a message service, an Internet service or the like through a communication network. According to an embodiment, the cellular module 821 may perform discrimination and authentication of the electronic device 801 within a communication network using the subscriber identification module 824 (e.g., a SIM card), for example. According to an embodiment, the cellular module 821 may perform at least a portion of functions that the processor 810 provides. According to an embodiment, the cellular module 821 may include a communication processor (CP).

Each of the Wi-Fi module 823, the BT module 825, the GNSS module 827, and the NFC module 828 may include a processor for processing data exchanged through a corresponding module, for example. According to an embodiment, at least a part (e.g., two or more elements) of the cellular module 821, the Wi-Fi module 823, the BT module 825, the GNSS module 827, or the NFC module 828 may be included within one Integrated Circuit (IC) or an IC package.

The RF module 829 may transmit and receive, for example, a communication signal (e.g., an RF signal). The RF module 829 may include, for example, a transceiver, a power amplifier module (PAM), a frequency filter, a low noise amplifier (LNA), an antenna, or the like. According to another embodiment, at least one of the cellular module 821, the Wi-Fi module 823, the BT module 825, the GNSS module 827, or the NFC module 828 may transmit and receive an RF signal through a separate RF module.

The subscriber identification module 824 may include, for example, a card and/or embedded SIM that includes a subscriber identification module and may include unique identify information (e.g., integrated circuit card identifier (ICCID)) or subscriber information (e.g., international mobile subscriber identity (IMSI)).

The memory 830 (e.g., the memory 130) may include an internal memory 832 or an external memory 834. For example, the internal memory 832 may include at least one of a volatile memory (e.g., a dynamic random access memory (DRAM), a static RAM (SRAM), or a synchronous DRAM (SDRAM)), a nonvolatile memory (e.g., a one-time programmable read only memory (OTPROM), a programmable ROM (PROM), an erasable and programmable ROM (EPROM), an electrically erasable and programmable ROM (EEPROM), a mask ROM, a flash ROM, a flash memory (e.g., a NAND flash memory, or a NOR flash memory), a hard drive, or a solid state drive (SSD).

The external memory 834 may include a flash drive, for example, compact flash (CF), secure digital (SD), micro secure digital (Micro-SD), mini secure digital (Mini-SD), extreme digital (xD), multimedia card (MMC), a memory stick, or the like. The external memory 834 may be functionally and/or physically connected with the electronic device 801 through various interfaces.

The sensor module 840 may measure, for example, a physical quantity or may detect an operation state of the electronic device 801. The sensor module 840 may convert the measured or detected information to an electrical signal. The sensor module 840 may include at least one of a gesture sensor 840A, a gyro sensor 840B, a barometric pressure sensor 840C, a magnetic sensor 840D, an acceleration sensor 840E, a grip sensor 840F, a proximity sensor 840G, a color sensor 840H (e.g., red, green, blue (RGB) sensor), a biometric sensor 840I, a temperature/humidity sensor 840J, an illuminance sensor 840K, or an UV sensor 840M. Even though not illustrated, additionally or alternatively, the sensor module 840 may include, for example, an E-nose sensor, an electromyography sensor (EMG) sensor, an electroencephalogram (EEG) sensor, an electrocardiogram (ECG) sensor, an infrared (IR) sensor, an iris sensor, and/or a fingerprint sensor. The sensor module 840 may further include a control circuit for controlling at least one or more sensors included therein. According to an embodiment, the electronic device 801 may further include a processor which is a part of the processor 810 or independent of the processor 810 and is configured to control the sensor module 840. The processor may control the sensor module 840 while the processor 810 remains at a sleep state.

The input device 850 may include various input circuitry, such as, for example, and without limitation, a touch panel 852, a (digital) pen sensor 854, a key 856, or an ultrasonic input unit 858. The touch panel 852 may use at least one of capacitive, resistive, infrared and ultrasonic detecting methods. Also, the touch panel 852 may further include a control circuit. The touch panel 852 may further include a tactile layer to provide a tactile reaction to a user.

The (digital) pen sensor 854 may be, for example, a portion of a touch panel or may include an additional sheet for recognition. The key 856 may include, for example, a physical button, an optical key, a keypad, or the like. The ultrasonic input device 858 may detect (or sense) an ultrasonic signal, which is generated from an input device, through a microphone (e.g., a microphone 888) and may check data corresponding to the detected ultrasonic signal.

The display 860 (e.g., the display 160) may include a panel 862, a hologram device 864, or a projector 866. The panel 862 may be configured the same as or similar to the display 160 of FIG. 1. The panel 862 may be implemented to be flexible, transparent or wearable, for example. The panel 862 and the touch panel 852 may be integrated into a single module. The hologram device 864 may display a stereoscopic image in a space using a light interference phenomenon. The projector 866 may project light onto a screen so as to display an image. The screen may be arranged inside or outside the electronic device 801. According to an embodiment, the display 860 may further include a control circuit for controlling the panel 862, the hologram device 864, or the projector 866.

The interface 870 may include various interface circuitry, such as, for example, and without limitation, a high-definition multimedia interface (HDMI) 872, a universal serial bus (USB) 874, an optical interface 876, or a D-subminiature (D-sub) 878. The interface 870 may be included, for example, in the communication interface 170 illustrated in FIG. 1. Additionally or alternatively, the interface 870 may include, for example, a mobile high definition link (MHL) interface, a SD card/multimedia card (MMC) interface, or an infrared data association (IrDA) standard interface.

The audio module 880 may convert a sound and an electrical signal in dual directions. At least a part of the audio module 880 may be included, for example, in the input/output interface 150 illustrated in FIG. 1. The audio module 880 may process, for example, sound information that is input or output through a speaker 882, a receiver 884, an earphone 886, or a microphone 888.

The camera module 891 for shooting a still image or a video may include, for example, at least one image sensor (e.g., a front sensor or a rear sensor), a lens, an image signal processor (ISP), or a flash (e.g., an LED or a xenon lamp).

The power management module 895 may manage, for example, power of the electronic device 801. According to an embodiment, a power management integrated circuit (PMIC) a charger IC, or a battery or fuel gauge may be included in the power management module 895. The PMIC may have a wired charging method and/or a wireless charging method. The wireless charging method may include, for example, a magnetic resonance method, a magnetic induction method or an electromagnetic method and may further include an additional circuit, for example, a coil loop, a resonant circuit, a rectifier, or the like. The battery gauge may measure, for example, a remaining capacity of the battery 896 and a voltage, current or temperature thereof while the battery is charged. The battery 896 may include, for example, a rechargeable battery or a solar battery.

The indicator 897 may display a specific state of the electronic device 801 or a part thereof (e.g., the processor 810), such as a booting state, a message state, a charging state, and the like. The motor 898 may convert an electrical signal into a mechanical vibration and may generate a vibration effect, a haptic effect, or the like. Even though not illustrated, a processing device (e.g., a GPU) for supporting a mobile TV may be included in the electronic device 801. The processing device for supporting a mobile TV may process media data according to the standards of digital multimedia broadcasting (DMB), digital video broadcasting (DVB), MediaFlo™, or the like.

According to various example embodiments, an electronic device includes an antenna that receives signals of multiple frequency bands from an external device, a receiver module that classifies and amplifies the signals received through the antenna, a conducting wire unit that transmits the amplified signals and a circuit unit that processes a signal received through the conducting wire unit, wherein the receiver module classifies the signals into a plurality of groups and selectively connects signals, which belong to at least one group of the plurality of groups, with an amplifier through a switch. The receiver module classifies the signals into a first band and a second band. The first and second bands are one of high and middle bands, middle and low bands, and high and middle bands.

According to various embodiments, the receiver module classifies the first band as a first group or a second group and classifies the second band as a third group. The receiver module amplifies the first group through a first amplifier and amplifies the second group after connecting the second group to a second amplifier through switching. The receiver module amplifies the third group after connecting the third group to a third amplifier through switching.

According to various embodiments, the first group comprises a signal of one frequency band, and the second group comprises signals of two or more frequency bands. The first group comprises a first communication band, wherein the second group comprises a second communication band, and wherein the first communication band and the second communication band are combined according to a carrier aggregation technology. The receiver module filters the first communication band and the second communication band by using a dual-SAW filter.

According to various embodiments, the conducting wire unit comprises a plurality of signal lines the number of which is less than the number of the multiple frequency bands. The conducting wire unit include a first signal line that transmits a signal of a first group and a second signal line that transmits a signal of a second group.

According to various embodiments, the receiver module separates the signals into first, second, and third bands, and the first, second, and third bands are high, middle, and low bands.

According to various embodiments, an electronic device includes a first antenna that receives signals of first and second frequency bands from another device, a classification unit that classifies the signals of the first and second frequency bands and has an input part connected with the first antenna, a first switch that selectively connects a plurality of filters, which support the first frequency band, with a first output part of the classification unit from which the signal of the first frequency band is output, a second switch that selectively connects an input part of a duplexer and one or more filters, which support the second frequency band, with a second output part of the classification unit from which the signal of the second frequency band is output, first to third amplifiers, a third switch that selectively connects an input part of the first amplifier with a plurality of filters supporting the first frequency band and a fourth switch that selectively connects at least one or more filters, which support the second frequency band, and a first output part of the duplexer with an input part of the second amplifier, wherein a second output part of the duplexer is connected with an input part of the third amplifier, and wherein output parts of the first to third amplifiers are connected with a transceiver through respective conducting wires.

According to various embodiments, the duplexer separates and filters signals of two communication bands included in the second frequency band.

According to various embodiments, the electronic device receives signals of three communication bands at the same time. The three communication bands are combined by carrier aggregation to perform a downlink.

According to various embodiments, a distance between the first antenna and the transceiver is larger than a distance between a second antenna and the transceiver. The second antenna transmits and receives signals of the first frequency band and the second frequency band.

Each of the above-mentioned elements may be configured with one or more components, and the names of the elements may be changed according to the type of the electronic device. The electronic device according to various embodiments may include at least one of the above-mentioned elements, and some elements may be omitted or other additional elements may be added. Furthermore, some of the elements of the electronic device according to various embodiments may be combined with each other so as to form one entity, so that the functions of the elements may be performed in the same manner as before the combination.

The term “module” used in this disclosure may represent, for example, a unit including one or more combinations of hardware (e.g., circuitry), software and firmware. For example, the term “module” may be interchangeably used with the terms “unit”, “logic”, “logical block”, “component” and “circuit”. The “module” may be a minimum unit of an integrated component or may be a part thereof. The “module” may be a minimum unit for performing one or more functions or a part thereof. The “module” may be implemented mechanically or electronically. For example, the “module” may include at least one of processing circuitry, an application-specific IC (ASIC) chip, a field-programmable gate array (FPGA), and a programmable-logic device for performing some operations, which are known or will be developed.

At least a portion of an apparatus (e.g., modules or functions thereof) or a method (e.g., operations) according to various embodiments may be, for example, implemented by instructions stored in a computer-readable storage media in the form of a program module. The instruction, when executed by a processor (e.g., the processor 120), may cause the one or more processors to perform a function corresponding to the instruction. The computer-readable storage media, for example, may be the memory 130.

The computer-readable storage media according to various embodiments may store a program for executing an operation in which a communication module receives an application package from an external device and provides the application package to a normal module of a processor, an operation in which the normal module determines whether a secure application is included in at least a portion of the application package, and an operation in which the secure module of the processor installs the secure application in the secure module or in a memory associated with the secure module.

The computer-readable storage media may include a hard disk, a floppy disk, a magnetic media (e.g., a magnetic tape), an optical media (e.g., a compact disc read only memory (CD-ROM) and a digital versatile disc (DVD)), a magneto-optical media (e.g., a floptical disk), and hardware devices (e.g., a read only memory (ROM), a random access memory (RAM), or a flash memory). Also, a program instruction may include not only a mechanical code such as things generated by a compiler but also a high-level language code executable on a computer using an interpreter. The above-mentioned hardware devices may be configured to operate as one or more software modules to perform operations according to various embodiments, and vice versa.

Modules or program modules according to various embodiments may include at least one or more of the above-mentioned elements, some of the above-mentioned elements may be omitted, or other additional elements may be further included therein. Operations executed by modules, program modules, or other elements according to various embodiments may be executed by a successive method, a parallel method, a repeated method, or a heuristic method. Also, a part of operations may be executed in different sequences, omitted, or other operations may be added.

An electronic device according to various embodiments of the present disclosure may group signals of multiple frequency bands and may selectively amplify the grouped signals, thereby reducing the number of amplifiers to be implemented and the number of signal lines to be implemented. This may mean that the efficiency of mounting components is improved and the interference with peripheral components is reduced.

The electronic device according to various embodiments of the present disclosure may amplify signals, which are combined according to a carrier aggregation technology, in different manners, thereby reducing the number of amplifiers and the number of signal lines. This may mean that signals based on the carrier aggregation technology are efficiently received and processed within a limited mounting space.

While the present disclosure has been illustrated and described with reference to various example embodiments thereof, it will be understood by those skilled in the art that various changes in form and details may be made therein without departing from the spirit and scope of the present disclosure as defined by the appended claims and their equivalents.

What is claimed is:

1. An electronic device comprising:
an antenna configured to receive signals of multiple frequency bands from an external device;
a receiver module comprising circuitry configured to classify and amplify the signals received through the antenna;
a conducting wire unit comprising a plurality of conducting wires configured to transmit the amplified signals; and
a circuit unit comprising circuitry configured to process a signal received through the conducting wires of the conducting wire unit,
wherein the receiver circuitry of the receiver module is configured to classify the signals into a plurality of groups and to selectively connect signals, which belong to at least one group of the plurality of groups, with an amplifier through a switch.

2. The electronic device of claim 1, wherein the circuitry of the receiver module is configured to classify the signals into a first band and a second band.

3. The electronic device of claim 2, wherein the first and second bands are one of: high and middle bands, middle and low bands, and high and middle bands.

4. The electronic device of claim 2, wherein the circuitry of the receiver module is configured to classify the first band as a first group or a second group and to classify the second band as a third group.

5. The electronic device of claim 4, wherein the circuitry of the receiver module is configured to amplify the first group through a first amplifier and to amplify the second group by connecting the second group to a second amplifier through switching.

6. The electronic device of claim 4, wherein the circuitry of the receiver module is configured to amplify the third group by connecting the third group to a third amplifier through switching.

7. The electronic device of claim 5, wherein the first group comprises a signal of one frequency band, and
the second group comprises signals of two or more frequency bands.

8. The electronic device of claim 5, wherein the first group comprises a first communication band,
the second group comprises a second communication band, and
the first communication band and the second communication band are combined based on a carrier aggregation technology.

9. The electronic device of claim 8, wherein the circuitry of the receiver module is configured to filter the first communication band and the second communication band by using a dual-SAW filter.

10. The electronic device of claim 1, wherein the conducting wire unit comprises a plurality of signal lines the number of which is less than the number of the multiple frequency bands.

11. The electronic device of claim 1, wherein the conducting wire unit comprises:
a first signal line that transmits a signal of a first group; and
a second signal line that transmits a signal of a second group.

12. The electronic device of claim 1, wherein the circuitry of the receiver module is configured to separate the signals into first, second, and third bands, and
wherein the first, second, and third bands are high, middle, and low bands.

13. An electronic device comprising:
a first antenna configured to receive signals of first and second frequency bands from another device;
a classification unit comprising classification circuitry configured to classify the signals of the first and second frequency bands and includes an input connected with the first antenna;
a first switch configured to selectively connect a plurality of filters, which support the first frequency band, with a first output of the classification unit from which the signal of the first frequency band is output;
a second switch configured to selectively connect an input of a duplexer and one or more filters, which support the second frequency band, with a second output of the classification unit from which the signal of the second frequency band is output;
first, second and third amplifiers;
a third switch configured to selectively connect an input of the first amplifier with a plurality of filters supporting the first frequency band; and
a fourth switch configured to selectively connect at least one or more filters, which support the second frequency band, and a first output of the duplexer with an input of the second amplifier,
wherein a second output of the duplexer is connected with an input of the third amplifier, and
wherein outputs of the first, second and third amplifiers are connected with a transceiver through respective conducting wires.

14. The electronic device of claim 13, wherein the duplexer is configured to separate and filter signals of two communication bands included in the second frequency band.

15. The electronic device of claim 13, wherein a distance between the first antenna and the transceiver is greater than a distance between a second antenna and the transceiver.

16. The electronic device of claim 15, wherein the second antenna is configured to transmit and receive signals of the first frequency band and the second frequency band.

17. A signal processing method performed by an electronic device, the method comprising:
receiving signals of multiple frequency bands through an antenna;
classifying the signals into a plurality of groups;
selectively connecting signals, which belong to at least one of the plurality of groups, with an amplifier through a switch;
transmitting amplified signals through a plurality of signal lines to a circuit unit comprising circuitry configured to process the amplified signals; and
processing the transmitted signals using the circuitry of the circuit unit.

18. The method of claim 17, wherein the classifying of the signals into the plurality of groups comprises:
classifying the signals into a first band and a second band.

19. The method of claim 18, wherein the classifying of the signals into the plurality of groups comprises:
classifying the first band as a first group or a second group; and
classifying the signal as a third group.

20. The method of claim 19, wherein the selectively connecting of the signals comprises:
amplifying the first group through a first amplifier; and
connecting the second group to a second amplifier through switching to amplify the second group.
